(19) United States
(12) Patent Application Publication
(10) Pub. No.: US 2025/0372430 A1
(43) Pub. Date: Dec. 4, 2025

(54) LOADING AND UNLOADING SYSTEM, CARRYING BOAT, SUCTION CUP ASSEMBLY, AND METHOD FOR LOADING WAFERS

(71) Applicant: Jiangsu Leadmicro Nano-Technology Co.,Ltd., WUXI (CN)

(72) Inventors: Da YAN, WUXI (CN); Fangyu FAN, WUXI (CN); Denghui LI, WUXI (CN); Xu KANG, WUXI (CN); Weihua ZHU, WUXI (CN)

(73) Assignee: Jiangsu Leadmicro Nano-Technology Co.,Ltd., WUXI (CN)

(21) Appl. No.: 19/299,863

(22) Filed: Aug. 14, 2025

Related U.S. Application Data
(63) Continuation of application No. PCT/CN2024/078518, filed on Feb. 26, 2024.

(30) Foreign Application Priority Data
Mar. 2, 2023 (CN) 202310195684.4

(51) Int. Cl. H01L 21/677; B25J 15/06; H01L 21/673

(52) U.S. Cl. CPC H01L 21/67781; B25J 15/0683; H01L 21/67313; H01L 21/67383; H01L 21/67386

(57) ABSTRACT

A loading and unloading system, a carrying boat, and a suction cup assembly are provided. The loading and unloading system includes a carrying boat, a cassette, and a suction cup assembly. The suction cup assembly is configured to transfer wafers between the carrying boat and the cassette. The carrying boat includes multiple stations defined along a first direction. Each station is configured to accommodate M wafers. The cassette is configured to accommodate N wafers. M and N are not equal.

### CROSS-REFERENCE TO RELATED APPLICATIONS

This application is a continuation of International Patent Application No. PCT/CN2024/078518, filed on Feb. 26, 2024, which claims priority to China Patent Applicant No. 202310195684.4, filed on Mar. 2, 2023, the entire contents of which are incorporated herein by reference.

### TECHNICAL FIELD

The present disclosure relates to the field of photovoltaic technologies, and in particular to a loading and unloading system, a carrying boat, a suction cup assembly, and a method for loading wafers.

### BACKGROUND

With an increasing demand for photovoltaic products, a requirement for capacity of a loading and unloading system becomes higher. In a production process of battery cells, multiple operations are involved, each typically requiring a different carrier to meet certain needs. For example, cassettes are adopted in wet processes, quartz boats are adopted in diffusion processes, and metal boats or so on are adopted in certain operations. The quantities of different carriers often vary. As technology advances, the quantity of the carrier in one operation may be different from the quantity of the carrier in another operation, rendering a wafer transfer between the different carriers a frequent necessity in production lines during the production process. Between many processing operations, the wafer transfer between the cassettes and the carrying boats is often required.

In existing market designs, on a host machine side, a common method to increase capacity of carrying boats for the wafers, such as aluminum boats used in atomic layer deposition (ALD), quartz boats used in diffusion annealing, or etc., is by stacking stations along a length direction of the carrying boats. The number of wafers carried in one station of the carrying boat is typically 1 time or 2 times of the number of wafers in the cassette. As a result, a calculated actual production capacity per carrying boat is 100*X (where X is the number of rows in the carrying boat) or 200*X (where X is the number of rows in the carrying boat) wafers. The only approach to boost capacity is by increasing the number rows in the carrying boat, which however leads to issues such as degraded coating uniformity, uneven film thickness, and etc., thereby affecting the performance of photovoltaic products.

Discovering new methods to increase capacity while achieving automated process between each operation is presented as an important challenge.

### SUMMARY

Some embodiments of the present disclosure may provide a loading and unloading system. The loading and unloading system may include a carrying boat, a cassette, and a suction cup assembly. The suction cup assembly may be configured to transfer wafers between the carrying boat and the cassette. The carrying boat may include a plurality of stations defined along a first direction. Each of the plurality of stations may be configured to accommodate M wafers. The cassette may be configured to accommodate N wafers. M may be not equal to N.

Some embodiments of the present disclosure may provide a carrying boat. The carrying boat may be configured in the loading and unloading system mentioned above. The carrying boat may include a carrying boat body and a plurality of support beams. The plurality of support beams may be disposed at intervals along the first direction within the carrying boat body and fixedly connected to two opposite sidewalls of the carrying boat body. Any adjacent two of the plurality of support beams may define a corresponding one of the plurality of stations. A plurality of clamping teeth may be disposed on each of the plurality of support beams along an extension direction of the plurality of support beams. The plurality of clamping teeth on each of the plurality of support beams may be disposed in one-to-one correspondence with the plurality of clamping teeth on an adjacent one the plurality of support beams. Any corresponding two of the plurality of clamping teeth may be configured to clamp at least one of the wafers.

Some embodiments of the present disclosure may provide a suction cup assembly. The suction cup assembly may include a base, at least two suction cup groups, and a driving mechanism. The at least two suction cup groups may be disposed on the base. Each of the at least two suction cup groups may include a plurality of suction cups disposed at intervals. The driving mechanism may be connected to the at least two suction cup groups and configured to drive the at least two suction cup groups to move on the base. The at least two suction cup groups may be configured to be driven by the driving mechanism to move toward each other until the plurality of suction cups are all spaced apart from each other in a second direction.

Some embodiments of the present disclosure may provide a method for loading wafers. The method may be applied in the loading and unloading system mentioned above. The suction cup assembly may include a base, at least two suction cup groups, and a driving mechanism. The at least two suction cup groups may be disposed on the base. Each of the at least two suction cup groups may include a plurality of suction cups disposed at intervals. The driving mechanism may be connected to the at least two suction cup groups and configured to drive the at least two suction cup groups to move on the base. The at least two suction cup groups may be configured to be driven by the driving mechanism to move toward each other until the plurality of suction cups are all spaced apart from each other in a second direction. The at least two suction cup groups may include a first suction cup group and a second suction cup group. The number of the plurality of suction cups in the first suction cup group may be 0.5N. The number of the plurality of suction cups in the second suction cup group may be 0.25N. The number of the cassette may be more than one. The more than one cassette may include a first cassette and a second cassette. N may be the number of the wafers loaded by each of the more than one cassette. The method may include: suctioning, by the first suction cup group, 0.5N wafers from the first cassette; and suctioning, by the second suction cup group, 0.25N wafers from the second cassette; driving, by the driving mechanism, the at least two suction cup groups to move toward each other until the plurality of suction cups are all spaced apart from each other in the second direction; releasing, by the at least two suction cup groups, all the currently suctioned wafers to a first station of the plurality of stations; and repeating above operations until the first station is fully loaded with the wafers.

Some embodiments of the present disclosure may provide a method for loading wafers. The method may be applied in the loading and unloading system mentioned above. The suction cup assembly may include a base, at least two suction cup groups, and a driving mechanism. The at least two suction cup groups may be disposed on the base. Each of the at least two suction cup groups may include a plurality of suction cups disposed at intervals. The driving mechanism may be connected to the at least two suction cup groups and configured to drive the at least two suction cup groups to move on the base. The at least two suction cup groups may be configured to be driven by the driving mechanism to move toward each other until the plurality of suction cups are all spaced apart from each other in a second direction. The at least two suction cup groups may include a first suction cup group and a second suction cup group. The number of the plurality of suction cups in the first suction cup group may be 0.5N. The number of the plurality of suction cups in the second suction cup group may be 0.25N. The number of the cassette may be more than one. The more than one cassette may include a third cassette, a fourth cassette, and a fifth cassette. N may be the number of the wafers loaded by each of the more than one cassette. The method may include: suctioning, by the first suction cup group, 0.5N wafers from the carrying boat; and suctioning, by the second suction cup group, 0.25N wafers from the carrying boat; releasing, by the first suction cup group, the 0.5N suctioned wafers into the third cassette; releasing, by the second suction cup group, the 0.25N suctioned wafers into the fourth cassette; repeating the above operations until the third cassette is fully loaded; suctioning, by the first suction cup group, 0.5N wafers from the carrying boat; suctioning, by the second suction cup group, 0.25N wafers from the carrying boat; releasing, by the first suction cup group, the 0.5N suctioned wafers into the fifth cassette; releasing, by the second suction cup group, the 0.25N suctioned wafers into the fourth cassette; and repeating the above operations.

### BRIEF DESCRIPTION OF THE DRAWINGS

In order to more clearly illustrate the technical solutions in some embodiments of the present disclosure, a brief introduction will be given below to the drawings required in the description of the embodiments. It is evident that the drawings described below are merely some embodiments of the present disclosure, and those skills in the art may obtain other drawings based on the following drawings without creative work.

FIG. 1 is a schematic structural view of a loading and unloading system according to some embodiments of the present disclosure.

FIG. 2 is a schematic structural view of a carrying boat shown in FIG. 1 according to some embodiments of the present disclosure.

FIG. 3 is a schematic partial structural view of a loading and unloading system according to some embodiments of the present disclosure.

FIG. 4 is a schematic structural view of a suction cup assembly shown in FIG. 1 according to some embodiments of the present disclosure.

### DETAILED DESCRIPTION

The technical solutions in some embodiments of the present disclosure will be clearly and completely described below with reference to the accompanying drawings. It is evident that the described embodiments are only part of the embodiments of the present disclosure and not all embodiments. Based on some embodiments of the present disclosure, all other embodiments obtained by those skills in the art without any creative work fall within the scope of the present disclosure.

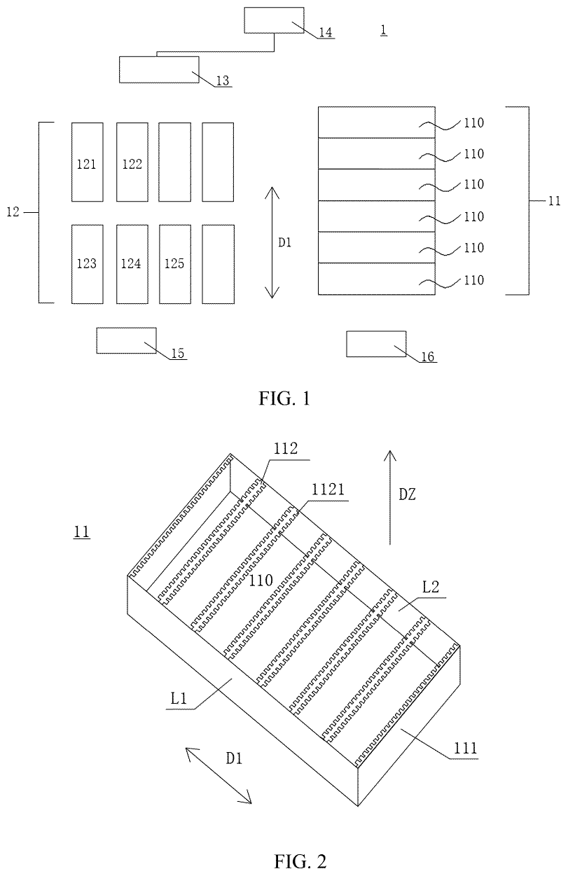

According to some embodiments of the present disclosure, as shown in FIG. 1, the loading and unloading system 1 may include a carrying boat 11, a cassette 12, and a suction cup assembly 13. The suction cup assembly 13 may be configured to transfer wafers between the carrying boat 11 and the cassette 12. The carrying boat 11 may include a plurality of stations 110 defined along a first direction D1 (for example, as shown in FIG. 1, the number of stations 110 in the carrying boat 11 may be seven). Each station 110 may be configured to accommodate or load or carry M wafers. The cassette 12 may be configured to load or carry or accommodate N wafers, where M may not be equal to N. The carrying boat 11 may be a quartz boat, a metal boat, or the like. Unprocessed wafers may be transferred from the carrying boat 11 to the cassette 12. The cassette 12 may be configured to transport or transfer the unprocessed wafers for processing (e.g., coating, cleaning, etc.). The processed wafers may then be transferred back from the cassette 12 to the carrying boat 11. Each station 110 may include a plurality of slots defined in sequence. The number of the slots may be equal to the number of the wafers carried by the carrying boat 11.

The above embodiments may enable a conversion between the number of wafers carried by the carrying boat 11 and the number of wafers carried by the cassette 12 through the suction cup assembly 13, in a case where the number of wafers carried per station 110 in the carrying boat 11 differs from the number of wafers carried by the cassette 12. As a result, a wafer loading efficiency may be improved and a capacity of the loading and unloading system 1 may be enhanced.

In some application scenarios, a ratio of M to N may be equal to 1.5 k, where k is a positive integer. The carrying boat 11 may adopt a single-insert mode or a double-insert mode based on actual needs. In the double-insert mode, two wafers may be inserted simultaneously in at least one of the slots that are configured to accommodate the wafers.

The above embodiments may enable a conversion between the number of wafers carried by the carrying boat 11 and the number of wafers carried by the cassette 12 through the suction cup assembly 13, in a case where the number of wafers carried per station 110 in the carrying boat 11 is 1.5 k times the number of wafers carried by the cassette 12. As a result, the wafer loading efficiency may be improved and the capacity of the loading and unloading system 1 may be enhanced.

Those skills in the art may select specific values of M and N according to production needs. For example, in some embodiments, M may be equal to 150 or 300, and N may be equal to 100. In this case, each station 110 in the carrying boat may include 150 slots for accommodating the wafers. In the single-insert mode, one unprocessed wafer may be accommodated per slot. In the double-insert mode, two unprocessed wafers may be accommodated per slot, which doubles the wafer loading capacity compared to the single-insert mode. In some embodiments, M may be equal to 174 or 348, and N may be equal to 116. In some embodiments, M may be equal to 180, 360, or 540, and N may be equal to 120. The above values of M and N may help enhance the carrying capacity of the carrying boat 11, improve a wafer transport efficiency of the carrying boat 11, and increase the capacity of the loading and unloading system 1.

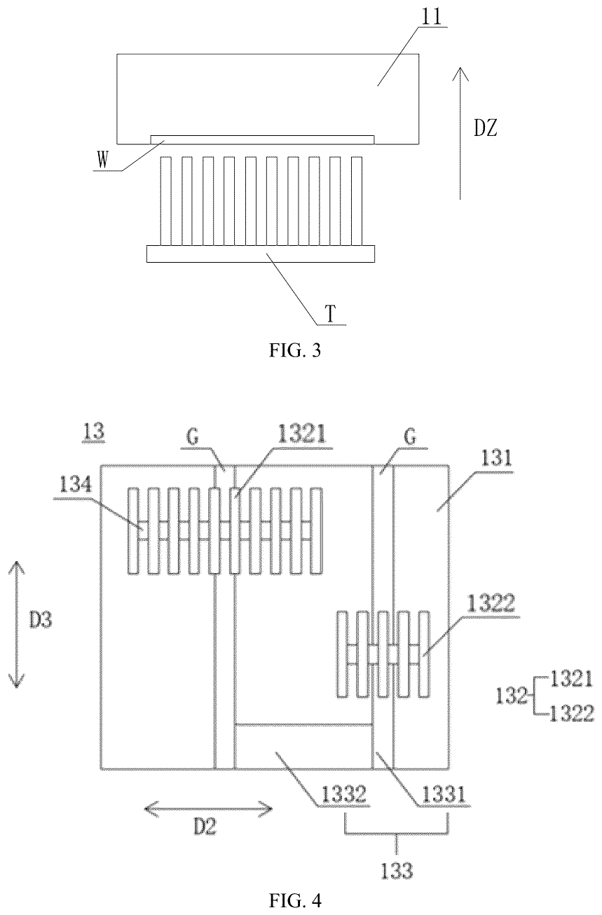

According to some embodiments of the present disclosure, as shown in FIG. 2 and FIG. 3. The loading and unloading system 1 may further include a support assembly T. A hollow region W may be defined at the bottom of the carrying boat 11. The support assembly T may reciprocate along a depth direction DZ of the stations 110 of the carrying boat 11 through the hollow region W. The support assembly T may be configured to transfer wafers between the suction cup assembly 13 and the carrying boat 11. In a case where the carrying boat 11 is about to load wafers, the support assembly T may be configured to pass through the hollow region W and raise in the direction DZ to a predetermined height. The suction cup assembly 13 may be configured to place the wafers onto the support assembly T. In a case where the wafers are finished being placed, the suction cup assembly 13 may be configured to move away and the support assembly T may descend in a direction opposite to the direction DZ until the wafers are dropped into the stations 110 of the carrying boat 11. At this point, the wafers may be finished being loaded on the carrying boat 11. Then, the support assembly T may be configured to further descend in the direction opposite to the direction DZ to reduce interference with the movement of the carrying boat 11. In a case where wafers need to be removed from the carrying boat 11, the support assembly T may be configured to raise in the direction DZ and push out the wafers in the stations 110. The suction cup assembly 13 may be configured to move to a corresponding position to suction or pick up and then transport the wafers.

In some application scenarios, the support assembly T may be configured to push out the wafers alternately. For example, the slots in each station 110 of the carrying boat may be divided into odd-numbered slots (1st, 3rd, 5th, 7th . . . ) and even-numbered slots (2nd, 4th, 6th, 8th . . . ), where the odd-numbered slots and the even-numbered slots are alternately defined. During the support assembly T pushes out the wafers in sequence, the support assembly T may be configured to push out only wafers in the odd-numbered slots or only wafers in the even-numbered slots. Because each suction cup may have a certain thickness, in a case where a spacing between adjacent wafers in the carrying boat 11 is relatively small and the thickness of each suction cup is greater than or equal to the spacing between the adjacent wafers, each suction cup may be difficult to be inserted between the adjacent wafers for pickup. Since the support assembly T may be configured to push out the wafers alternately, a spacing between the adjacent pushed-out wafers may be increased, thereby providing enough room for the suction cups to be inserted.

In some embodiments, a distance between any adjacent two wafers carried by the support assembly T may be substantially equal to a distance between any two alternating slots in the carrying boat 11.

According to some embodiments of the present disclosure, the multiple wafers carried in each station 110 of the carrying boat 11 may be arranged in a direction substantially perpendicular to the first direction D1. The wafers carried by the cassette 12 may be arranged in a direction different from the first direction D1. The loading and unloading system 1 may further include a first moving mechanism 14. The suction cup assembly 13 may be disposed on the first moving mechanism 14. The first moving mechanism 14 may be configured to drive the suction cup assembly 13 to move. The first moving mechanism 14 may include a robotic arm or a gantry structure. In a case where the suction cup assembly 13 finishes suctioning wafers from the cassette 12, the first moving mechanism 14 may be configured to drive the suction cup assembly 13 to rotate by a predetermined angle, thereby further driving the wafers suctioned by the suction cup assembly 13 to substantially rotate by the predetermined angle. The first moving mechanism 14 may then be configured to further drive the suction cup assembly 13 to move until the suction cup assembly 13 places the suctioned wafers onto the stations 110 of the carrying boat 11. Those skills in the art may select the predetermined angle based on process requirements and equipment structure. The predetermined angle may be, for example, 10 degrees, 30 degrees, 45 degrees, 60 degrees, 90 degrees, 145 degrees, or etc. The first moving mechanism 14 may be configured to drive the suction cup assembly 13 to rotate by a certain angle. As a result, in ab case where an arrangement direction of the wafers carried by each station 110 of the carrying boat 11 is different from an arrangement direction of the wafers carried by the cassette 12, a conversion between the wafer arrangement direction of the carrying boat 11 and the wafer arrangement direction of the cassette 12 may be enabled, without having to arrange an additional rotating mechanism to rotate the first moving mechanism 14. As a result, the wafers may be smoothly transferred and loaded between the carrying boat 11 and the cassette 12, enhancing a compactness of the loading and unloading equipment and reducing footprint of the loading and unloading equipment.

In some application scenarios, as shown in FIG. 1, the predetermined angle may be substantially equal to 90 degrees, such that the compactness of the loading and unloading system 1 may be enhanced and the footprint of the loading and unloading equipment may be reduced.

According to some embodiments of the present disclosure, the loading and unloading system 1 may further include a second moving mechanism 15. The second moving mechanism 15 may be configured to drive the cassette 12 to move in the first direction D1. The cassette 12 may be configured to reciprocate along the first direction D1 to form a cassette channel. For example, as shown in FIG. 1, the number of the cassette channel formed by the cassette 12 in the first direction D1 may be four. As a result, the first moving mechanism 14 may be configured to pick up wafers from different cassettes 12 across the first direction D1 and from different positions in a single cassette 12 without having to move in the first direction D1. The movement of the first moving mechanism 14 in a direction substantially perpendicular to the first direction D1 and the movement of the cassette 12 in the first direction D1 may proceed simultaneously, which may effectively improve the loading and unloading efficiency and increase the capacity of the loading and unloading system 1, with a simple and easily implementable structure. In this case, a stacking direction of the wafers in the cassette 12 may be the first direction D1.

In some embodiments, as shown in FIG. 1, the loading and unloading system 1 may further include a third moving mechanism 16. The third moving mechanism 16 may be configured to drive the carrying boat 11 to reciprocate in the first direction D1. In this case, the first moving mechanism 14 may be configured to place the wafers suctioned by the suction cup assembly 13 into different stations 110 without having to move in the first direction D1. In this case, an arrangement direction of the stations 110 of the carrying boat 11 may be the first direction D1 and the wafers in the stations 110 may be arranged in a direction substantially perpendicular to the first direction D1, which may effectively improve the loading and unloading efficiency and increase the capacity of the loading and unloading system 1, with a simple and easily implementable structure.

According to some embodiments of the present disclosure, as shown in FIG. 2, the carrying boat 11 may include a carrying boat body 111 and support beams 112. The number of support beams 112 may be more than one. The support beams 112 may be disposed at intervals along the first direction D1 in the carrying boat body 111, and may be fixedly connected to two opposite sidewalls L1 and L2 of the carrying boat body 111. Each station 110 may be defined between any adjacent two support beams 112. A plurality of clamping teeth 1121 may be disposed on each support beam 112 along an extension direction of the support beams 112. The clamping teeth 1121 on each support beam 112 may be disposed in one-to-one correspondence with the clamping teeth 1121 on an adjacent support beam 112. Any corresponding two clamping teeth 1121 may be configured to clamp the wafer. Each slot may be defined by corresponding two clamping teeth 112 on adjacent support beams 112. As a result, multiple stations 110 may be integrated into a single carrying boat 11, improving a structural compactness of the carrying boat 11 and enhancing a stability of relative positions between multiple stations 110 during transportation, unloading, and loading of the carrying boat 11.

Further, in some embodiments, the carrying boat body 111 of the carrying boat 11 may be integrally formed, which results in an integrally formed carrying boat, thereby enhancing a strength of the carrying boat 11 and simplifying a manufacturing process of the carrying boat 11.

According to some embodiments of the present disclosure, as shown in FIG. 1 and FIG. 4. The suction cup assembly 13 may include a base 131, at least two suction cup groups 132, and a driving mechanism 133. The at least two suction cup groups 132 may be disposed on the base 131. Each suction cup group 132 may include a plurality of suction cups disposed at intervals. The driving mechanism 133 may be connected to the at least two suction cup groups 132 and configured to drive the at least two suction cup groups 132 to move on the base 131. The at least two suction cup groups 132 may be configured to be driven by the driving mechanism 133 to move toward each other until the suction cups are all spaced apart from each other in a second direction D2. According to the above embodiments, wafers may be picked up by the at least two suction cup groups 132 and the suction cup groups 132 may be controlled to move toward each other, directly by the driving mechanism 133 on the suction cup assembly 13, so as to perform a wafer merging operation on the wafers suctioned by at least two suction cups, which improves the efficiency of wafer loading. Further, the suction cup assembly 13 may have a compact structure, which reduces the footprint of the loading and unloading system 1. Before the two suction cup groups 132 move toward each other, a distance between the two suction cup groups 132 may substantially be equal to a distance between wafers carried in adjacent two cassettes along a direction substantially perpendicular to the second direction D2. In this way, the two suction cup groups 132 may be directly aligned, in physical, with the wafers in the adjacent cassettes when suctioning the wafers, without requiring additional mechanical movement. In some embodiments, the above movement may be implemented by sliding.

The second direction D2 may be substantially parallel to or not parallel to the first direction D1. The multiple suction cups may be disposed at equal intervals, where the interval may correspond to a distance between the adjacent clamping teeth 1121 that are configured to fix the wafers in the stations 110 of the carrying boat 11.

A suction region may be defined on a main surface of each suction cup. A vacuum channel may be disposed inside the suction cup. The vacuum channel may be configured to connect the suction region and a vacuum device. In a case where the vacuum device is connected to the vacuum channel and performs a vacuum operation, a vacuum environment may be formed between the suction region and the wafers, thereby enabling the wafers to be suctioned onto the main surface of the suction cup.

According to some embodiments of the present disclosure, the driving mechanism 133 may include a rail assembly 1331 and a motor 1332. The rail assembly 1331 may be disposed on the base 131. The at least two suction cup groups 132 may be movably disposed on the rail assembly 1331. The motor 1332 may be connected to the at least two suction cup groups 132 and may be configured to drive the at least two suction cup groups 132 to move along the rail assembly 1331. The driving mechanism 133 may have a simple structure, high movement stability, and may facilitate adjustment of the movement distance of the at least two suction cup groups 132, thereby improving an alignment of the wafers after merging.

According to some embodiments of the present disclosure, the rail assembly 1331 may include at least two rails G disposed on the base 131. The at least two rails G may correspond one-to-one to the at least two suction cup groups 132. Each suction cup groups 132 may be movably disposed on a corresponding one of the rails G. In this way, mutual interference between different suction cup groups 132 when moving on the rails G may be reduced, simplifying the structure of the suction cup assembly 13. In some embodiments, the at least two suction cup groups 132 may move simultaneously on a single rail G. In some embodiments, one of the at least two suction cup groups 132 may remain stationary while the remaining of the at least two suction cup groups 132 may be configured to move toward the stationary one of the at least two suction cup groups 132 to perform the wafer merging operation.

According to some embodiments of the present disclosure, all suction cups in each suction cup group 132 may be disposed at intervals in a direction parallel to the second direction D2. The suction cup groups 132 may be configured to be driven by the driving mechanism 133 to all move in a direction substantially perpendicular to the second direction D2. In this way, the suction cup assembly 13 may be enabled to have a compact structure, which reduces a size of the suction cup assembly 13.

According to some embodiments of the present disclosure, the suction cup assembly 13 may further include connection beams 134. The connection beams 134 may be disposed on the base 131 and extend along the second direction D2. The plurality of suction cups in the suction cup groups 132 may be disposed at intervals on the connection beams 134. The connection beams 134 may be configured to improve a mounting stability of the suction cups.

According to some embodiments of the present disclosure, the at least two suction cup groups 132 may include a first suction cup group 1321 and a second suction cup group 1322. The number of suction cups in the first suction cup group 1321 may be different from the number of suction cups in the second suction cup group 1322. In this way, in a case where the wafer holding capacity of each station 110 of the carrying boat 11 is different from the wafer holding capacity of the cassette 12, the first suction cup group 1321 and the second suction cup group 1322 may be respectively configured to suction different numbers of wafers and then perform the wafer merging operation to enable a conversion of the wafer quantities between each station 110 of the carrying boat 11 and the cassette 12, thereby effectively improving the efficiency of loading and unloading.

According to some embodiments of the present disclosure, the at least two suction cup groups 132 may include a first suction cup group 1321 and a second suction cup group 1322. The number of suction cups in the first suction cup group 1321 may be twice the number of suction cups in the second suction cup group 1322. In this way, in a case where the wafer holding capacity of each station 110 of the carrying boat 11 is 1.5 k times the wafer holding capacity of the cassette 12 (where k is a positive integer), the loading and unloading efficiency may be effectively improved.

According to some embodiments of the present disclosure, the suction cup assembly 13 may further include an aligning member. The aligning member may be configured to align the wafers, in a case where the two suction cup groups move toward each other. According to some embodiments of the present disclosure, the suction cup assembly 13 may further include a positioning assembly. The positioning assembly may be configured to adjust a fixed distance between the at least two suction cup groups 132 in a direction substantially perpendicular to the second direction D2, so as to adapt to different placements and spacing requirements of the cassette 12, thereby improving the compatibility of the suction cup assembly 13.

The above-mentioned loading and unloading system 1 may be configured to load wafers. As shown in FIG. 1 and FIG. 4, in some application scenarios, the wafers carried on the cassette 12 may need to be transferred into the carrying boat 11. The suction cup assembly 13 may include the base 131, the at least two suction cup groups 132, and the driving mechanism 133. The at least two suction cup groups 132 may be disposed on the base 131. Each suction cup group 132 may include the plurality of suction cups disposed at intervals. The driving mechanism 133 may be connected to the at least two suction cup groups 132 and may be configured to drive the at least two suction cup groups 132 to move on the base 131. The at least two suction cup groups 132 may be configured to move toward each other under the drive of the driving mechanism 133 until the suction cups are all spaced apart from each other in the second direction D2. The at least two suction cup groups 132 may include a first suction cup group 1321 and a second suction cup group 1322. The number of suction cups in the first suction cup group 1321 may be 0.5N. The number of suction cups in the second suction cup group 1322 may be 0.25N, where k may be equal to 1. The number of cassette 12 may be more than one. The more than one cassette 12 may include a first cassette 121 and a second cassette 122. A method for loading wafers may include the following operations. The first suction cup group 1321 may suction 0.5N wafers from the first cassette 121. The second suction cup group 1322 may suction 0.25N wafers from the second cassette 122. The at least two suction cup groups may be driven by the driving mechanism 133 to move toward each other, until all suction cups are spaced apart from each other in the second direction D2. The at least two suction cup groups 132 may release all the currently suctioned wafers to a first station of the plurality of stations 110. The above operations may be repeated such that the first station 110 is fully loaded with the wafers. The first station may refer to any one of the multiple stations 110, which may be selected by those skills in the art based on a current state of the loading and unloading system 1 and a position of the carrying boat 11. In this way, the suction cup assembly 13 may perform the suction operation for two times, one for the wafers in the first cassette 121 and the other one for the wafers in the second cassette 122, which enables all the wafers in both the first cassette 121 and the second cassette 122 to be transferred to one of the stations 110 in the carrying boat 11, thereby effectively improving the efficiency of wafer transfer and increasing the capacity of the loading and unloading system 1.

In some embodiments, as shown in FIG. 3, the loading and unloading system 1 may further include the support assembly T. A process of the at least two suction cup groups 132 releasing all the currently suctioned wafers to a first station of the plurality of stations 110 may include the following operations. The support assembly T may raise along the direction DZ to a predetermined height. The suction cup assembly 13 may place the wafers onto the support assembly T. In a case where the wafers are finished being placed, the suction cup assembly 13 may move away and the support assembly T may descend or lower in a direction opposite to the direction DZ. At this point, the wafers may be dropped into the first station of the carrying boat 11 and the wafers are finished being loaded to the carrying boat 11. The above operations may be repeated, so as to finish loading the wafers into other empty stations. In a case where the wafers are removed from the carrying boat 11, a reverse operation may be performed to achieve wafer retrieving.

In some embodiments, the carrying boat 11 may include the carrying boat body 111 and the support beams 112. The number of support beams 112 may be more than one. The support beams 112 may be disposed at intervals along the first direction D1 in the carrying boat body 111, and may be fixedly connected to the two opposite sidewalls L1 and L2 of the carrying boat body 111. The stations 110 may be formed between the adjacent two support beams 112. The plurality of clamping teeth 1121 may be disposed on each support beam 112 along the extension direction of the support beams 112. The clamping teeth 1121 on each support beam 112 may be disposed in one-to-one correspondence with the clamping teeth 1121 on an adjacent support beam 112. The corresponding two clamping teeth 1121 may be configured to clamp the wafer. Each slot may be defined by corresponding two clamping teeth 112 on adjacent support beams 112. The distance between any adjacent two wafers carried by the support assembly T may be substantially equal to the distance between any two alternating slots in the carrying boat 11.

In some embodiments, as shown in FIG. 1 and FIG. 4, before the operation of the first suction cup group 1321 suctioning 0.5N wafers from the first cassette 121 and the second suction cup group 1322 suctioning 0.25N wafers from the second cassette 122, the method may further include the following operation. A distance between the first suction cup group 1321 and the second suction cup group 1322 along the third direction D3 may be controlled to be substantially equal to a distance between the first cassette 121 and the second cassette 122 along the third direction D3. The third direction D3 may be substantially perpendicular to the second direction D2. The first cassette 121 and the second cassette 122 may be disposed adjacent to each other. In this way, positions of the suction cups in the first suction cup group 1321 may correspond one-to-one with positions of the wafers in the first cassette 121. Positions of the suction cups in the second suction cup group 1322 may correspond one-to-one with positions of the wafers in the second cassette 122. As a result, the suction cup assembly 13 may be configured to suction wafers from both the first cassette 121 and the second cassette 122, thereby improving the wafer suction efficiency and enhancing the capacity of the loading and unloading equipment.

In some other application scenarios of the present disclosure, the wafers carried on the carrying boat 11 may need to be transferred into the cassette 12. The suction cup assembly 13 may include the base 131, the at least two suction cup groups 132, and the driving mechanism 133. The at least two suction cup groups 132 may be disposed on the base 131. Each suction cup group 132 may include the plurality of suction cups disposed at intervals. The driving mechanism 133 may be connected to the at least two suction cup groups 132 and may be configured to drive the at least two suction cup groups 132 to move on the base 131. The at least two suction cup groups 132 may be configured to move toward each other under the drive of the driving mechanism 133 until the suction cups are all spaced apart from each other in the second direction D2. The at least two suction cup groups 132 may include a first suction cup group 1321 and a second suction cup group 1322. The number of suction cups in the first suction cup group 1321 may be 0.5N. The number of suction cups in the second suction cup group 1322 may be 0.25N, where k may be equal to 1. The number of cassette 12 may be more than one. The more than one cassette 12 may include a third cassette 123, a fourth cassette 124, and a fifth cassette 125. A method for loading wafers may include the following operations. The first suction cup group 1321 may suction 0.5N wafers from the carrying boat 11. The second suction cup group 1322 may suction 0.25N wafers from the carrying boat 11. The first suction cup group 1321 may release the suctioned 0.5N wafers into the third cassette 123. The second suction cup group 1322 may release the suctioned 0.25N wafers into the fourth cassette 124. The above operations may be repeated. The first suction cup group 1321 may suction 0.5N wafers from the carrying boat 11. The second suction cup group 1322 may suction 0.25N wafers from the carrying boat 11. The first suction cup group 1321 may release the suctioned 0.5N wafers into the fifth cassette 125. The second suction cup group 1322 may release the suctioned 0.25N wafers into the fourth cassette 124. The above operations may be repeated. In this way, the suction cup assembly 13 may perform the suction operation for four times on the wafers in one of the stations to transfer all the wafers in the one station of the carrying boat 11 to three cassettes 12, thereby effectively improving wafer transfer efficiency and enhancing the capacity of the loading and unloading system 1.

In some further embodiments, the loading and unloading system 1 may further include the support assembly T. A process of the first suction cup group 1321 suctioning the wafers from the carrying boat 11 may include the following operations. The support assembly T may raise to push out a part of wafers in the carrying boat 11. In a case where the support assembly T raises to a predetermined height, the suction cup assembly 13 may suction and transfer the wafers. After the part of the wafers is finished being transferred, the support assembly T may push out another portion of the wafers. The above operations may be repeated until all the wafers are finished being transferred. The wafers may be pushed out from the stations 110 of the carrying boat 11, thereby facilitating the suction cups to suction the wafers.

In some further embodiments, the support assembly T may push the wafers out of the carrying boat 11 alternately. In this manner, as described above, pushing the wafers alternately by the support assembly T may increase the spacing between the pushed-out wafers, thereby providing sufficient space for insertion of the suction cups. In some embodiments, N may be equal to 100, i.e., each cassette 12 may carry 100 wafers. A lead screw translation structure may be designed at an end of the cassette. The number of the suction cups in the first suction cup group may be 50. The number of the suction cups in the second suction cup group may be 25. An operation logic may be as follows. First, the processed wafers may be suctioned from a first set of slots (i.e., 1st, 3rd, 5th . . . 147th, 149th) of a single first station in the carrying boat and placed into empty dry cassettes, where 50 processed wafers may be placed into an empty first dry cassette and 25 processed wafers may be placed into an empty second dry cassette. Then, empty suction cups may move to suction all the wafers from a second set of slots (i.e., 2nd, 4th, 6th . . . 148th, 150th) of the first station in the carrying boat and place the suctioned wafers again into the first dry cassette and the second dry cassette, with 50 wafers placed into the first dry cassette and 25 wafers placed into the second dry cassette. At this point, the first dry cassette may become a full dry cassette. A cassette-handling robot may remove the full first dry cassette and then replace the full first dry cassette with a new empty third dry cassette. Further, a wafer-handling robot may move to a carrying boat channel with an empty load. The wafers in a first set of slots (i.e., 1st, 3rd, 5th . . . 147th, 149th) of the second station in the carrying boat may all be suctioned and placed into the new empty third dry cassette and the original second dry cassette. Then, the wafers in a second set of slots (i.e., 2nd, 4th, 6th . . . 148th, 150th) of the second station in the carrying boat may all be suctioned and placed into the third dry cassette and the second dry cassette. At this point, the third dry cassette and the second dry cassette may both become full dry cassettes. A robotic arm may move, with an empty load, to extract all wafers from a wet cassette. The cassette-handling robot may replace the two full dry cassettes with empty dry cassettes. The process of extracting wafers from the wet cassette and placing the extracted wafers into the carrying boat 11 may be a reverse process of the extracting wafers from the carrying boat 11 and placing the extracted wafers into the empty dry cassette. During the above process, the processed wafers on the station may be completely removed first and the unprocessed wafers may then be loaded. In some embodiments, after the processed wafers are placed into the cassette, the unprocessed wafers may be directly picked up and then be placed into the empty slots during the return trip. The above process may be optimized through related operations to further reduce the running time of the mechanical structures on both the cassettes and the carrying boat 11.

In addition, the number of wafers in the cassette 12 may further be 116, 120, or so on. In this case, a method for loading wafers may be similar to the above and will not be repeated herein.

As described above, the loading and unloading system in some embodiments of the present disclosure may include the carrying boat, the cassette, and the suction cup assembly. The suction cup assembly may be configured to transfer wafers between the carrying boat and the cassette. The carrying boat may include a plurality of stations defined along the first direction. Each station may be configured to accommodate M wafers and the cassette may be configured to carry N wafers, where M and N may be not equal. By means of the above arrangement, the conversion between the number of wafers carried by the carrying boat and the number of wafers carried by the cassette may be enabled, thereby improving wafer loading efficiency and enhancing the capacity of the loading and unloading system.

The above are merely some embodiments of the present disclosure and should not be construed as limiting the scope of the present disclosure. Based on the description and drawings of the present disclosure, any equivalent structural or process modifications, or any direct or indirect applications in other related technical fields, shall fall within the scope of the present disclosure.

1. A loading and unloading system, comprising:
a carrying boat;
a cassette; and
a suction cup assembly, configured to transfer wafers between the carrying boat and the cassette;
wherein the carrying boat comprises a plurality of stations defined along a first direction, each of the plurality of stations is configured to accommodate M wafers, the cassette is configured to accommodate N wafers, and M is not equal to N.

2. The loading and unloading system as claimed in claim 1, wherein a ratio of M to N is equal to 1.5 k, and k is a positive integer.

3. The loading and unloading system as claimed in claim 1, wherein
M is equal to 150 or 300, and N is equal to 100; or
M is equal to 174 or 348, and N is equal to 116; or
M is equal to 180, 360, or 540, and N is equal to 120.

4. The loading and unloading system as claimed in claim 1, further comprising:
a support assembly, configured to move along a depth direction of the plurality of stations of the carrying boat and configured to assist in transferring the wafers between the suction cup assembly and the carrying boat.

5. The loading and unloading system as claimed in claim 1, wherein the wafers accommodated by each of the plurality of stations of the carrying boat are disposed in a direction substantially perpendicular to the first direction, and the wafers accommodated by the cassette are disposed along the first direction; and
the loading and unloading system further comprises:
a first moving mechanism, configured to drive the suction cup assembly to move, wherein the suction cup assembly is disposed on the first moving mechanism;
wherein in a case where the suction cup assembly finishes suctioning the wafers from the cassette, the first moving mechanism is configured to drive the suction cup assembly to rotate by a predetermined angle, for enabling the wafers suctioned by the suction cup assembly to rotate by the predetermined angle, and the first moving mechanism is then further configured to drive the suction cup assembly to move until the suction cup assembly places the wafers suctioned by the first moving mechanism onto the plurality of stations of the carrying boat.

6. The loading and unloading system as claimed in claim 5, wherein the predetermined angle is substantially 90 degrees.

7. A carrying boat, configured in the loading and unloading system as claimed in claim 1, and comprising:
a carrying boat body;
a plurality of support beams, disposed at intervals along the first direction within the carrying boat body and fixedly connected to two opposite sidewalls of the carrying boat body, wherein any adjacent two of the plurality of support beams define a corresponding one of the plurality of stations; and
a plurality of clamping teeth, disposed on each of the plurality of support beams along an extension direction of the plurality of support beams, wherein the plurality of clamping teeth on each of the plurality of support beams are disposed in one-to-one correspondence with the plurality of clamping teeth on an adjacent one the plurality of support beams and any corresponding two of the plurality of clamping teeth are configured to clamp at least one of the wafers.

8. A suction cup assembly, configured in the loading and unloading system as claimed in claim 1, and comprising:
a base;
at least two suction cup groups, disposed on the base and each comprising a plurality of suction cups disposed at intervals; and
a driving mechanism, connected to the at least two suction cup groups and configured to drive the at least two suction cup groups to move on the base, wherein the at least two suction cup groups are configured to be driven by the driving mechanism to move toward each other until the plurality of suction cups are all spaced apart from each other in a second direction.

9. The suction cup assembly as claimed in claim 8, wherein the driving mechanism comprises:
a rail assembly, disposed on the base, wherein the at least two suction cup groups are disposed on the rail assembly; and
a motor, connected to the at least two suction cup groups and configured to drive the at least two suction cup groups to move on the rail assembly.

10. The suction cup assembly as claimed in claim 9, wherein
the rail assembly comprises at least two rails disposed on the base, the at least two suction cup groups have an one-to-one correspondence with the at least two rails, and each of the at least two suction cup groups is disposed on a corresponding one of the at least two rails.

11. The suction cup assembly as claimed in claim 10, wherein
the plurality of suction cups of each of the at least two suction cup groups are spaced apart from each other in a direction parallel to the second direction; and
the at least two suction cup groups are driven by the driving mechanism to move in a direction substantially perpendicular to the second direction.

12. The suction cup assembly as claimed in claim 11, further comprising:
a plurality of connection beams, disposed on the base and extending along the second direction, wherein the plurality of suction cups of each of the at least two suction cup groups are disposed on the plurality of connection beams at intervals.

13. The suction cup assembly as claimed in claim 8, wherein the at least two suction cup groups comprise a first suction cup group and a second suction cup group, the number of the plurality of suction cups in the first suction cup group is different from the number of the plurality of suction cups in the second suction cup group.

14. A method for loading wafers, applied in the loading and unloading system as claimed in claim 1,
wherein the suction cup assembly comprises:
a base;
at least two suction cup groups, disposed on the base and each comprising a plurality of suction cups disposed at intervals; and
a driving mechanism, connected to the at least two suction cup groups and configured to drive the at least two suction cup groups to move on the base, wherein the at least two suction cup groups are configured to be driven by the driving mechanism to move toward each other until the plurality of suction cups are all spaced apart from each other in a second direction;
wherein the at least two suction cup groups comprise a first suction cup group and a second suction cup group, the number of the plurality of suction cups in the first suction cup group is 0.5N, the number of the plurality of suction cups in the second suction cup group is 0.25N;
the number of the cassette is more than one, the more than one cassette comprises a first cassette and a second cassette, and N is the number of the wafers loaded by each of the more than one cassette; and
the method comprises:
suctioning, by the first suction cup group, 0.5N wafers from the first cassette; and suctioning, by the second suction cup group, 0.25N wafers from the second cassette;
driving, by the driving mechanism, the at least two suction cup groups to move toward each other until the plurality of suction cups are all spaced apart from each other in the second direction;
releasing, by the at least two suction cup groups, all the currently suctioned wafers to a first station of the plurality of stations; and
repeating above operations until the first station is fully loaded with the wafers.

15. The method as claimed in claim 14, wherein the loading and unloading system further comprises a support assembly; and
the releasing, by the at least two suction cup groups, all the currently suctioned wafers to a first station of the plurality of stations, comprises:
raising the support assembly to a predetermined height;
placing, by the suction cup assembly, the wafers onto the support assembly; and
moving away the suction cup assembly and lowering the support assembly, in a case where the wafers are finished being placed, such that the wafers are dropped into the first station of the carrying boat and the wafers are finished being loaded to the carrying boat.

16. The method as claimed in claim 15, wherein a plurality of slots are defined in each one of the plurality of stations of the carrying boat in sequence, and a distance between any adjacent two of the wafers carried by the support assembly is substantially equal to a distance between any alternating two of the plurality of slots in the carrying boat.

17. The method as claimed in claim 16, before the suctioning, by the first suction cup, 0.5N wafers from the first cassette, and suctioning, by the second suction cup group, 0.25N wafers from the second cassette, the method further comprises:
controlling a distance between the first suction cup group and the second suction cup group along a third direction to be substantially equal to a distance between the first cassette and the second cassette along the third direction, wherein the third direction is substantially perpendicular to the second direction.

18. A method for loading wafers, applied in the loading and unloading system as claimed in claim 1,
wherein the suction cup assembly comprises:
a base;
at least two suction cup groups, disposed on the base and each comprising a plurality of suction cups disposed at intervals; and
a driving mechanism, connected to the at least two suction cup groups and configured to drive the at least two suction cup groups to move on the base, wherein the at least two suction cup groups are configured to be driven by the driving mechanism to move toward each other until the suction cups are all spaced apart from each other in a second direction;
wherein the at least two suction cup groups comprise a first suction cup group and a second suction cup group, the number of the plurality of suction cups in the first suction cup group is 0.5N, the number of the plurality of suction cups in the second suction cup group is 0.25N;
the number of the cassette is more than one, the more than one cassette comprises a third cassette, a fourth cassette, and a fifth cassette, and N is the number of the wafers loaded by each of the more than one cassette; and
the method comprises:
suctioning, by the first suction cup group, 0.5N wafers from the carrying boat; and suctioning, by the second suction cup group, 0.25N wafers from the carrying boat;
releasing, by the first suction cup group, the 0.5N suctioned wafers into the third cassette;
releasing, by the second suction cup group, the 0.25N suctioned wafers into the fourth cassette;
repeating the above operations until the third cassette is fully loaded;
suctioning, by the first suction cup group, 0.5N wafers from the carrying boat; suctioning, by the second suction cup group, 0.25N wafers from the carrying boat; releasing, by the first suction cup group, the 0.5N suctioned wafers into the fifth cassette; releasing, by the second suction cup group, the 0.25N suctioned wafers into the fourth cassette; and
repeating the above operations.

19. The method as claimed in claim 18, wherein the loading and unloading system further comprises a support assembly, wherein the suctioning, by the first suction cup group, wafers from the carrying boat, comprises:
raising the support assembly to push out a part of the wafers in the carrying boat from the carrying boat;
suctioning and transferring, by the suction cup assembly, the wafers in a case where the support assembly raises to a predetermined height; and
repeating above operations until all the wafers are finished being transferred.

20. The method as claimed in claim 19, wherein the support assembly is configured to push out the wafers from the carrying boat alternately.
